(19) United States
(12) Patent Application Publication
(10) Pub. No.: US 2024/0380332 A1
(43) Pub. Date: Nov. 14, 2024

(54) HALF-BRIDGE ARRANGEMENT OF AN INVERTER OF AN ELECTRIC DRIVE OF A VEHICLE

(71) Applicant: ZF Friedrichshafen AG, Friedrichshafen (DE)

(72) Inventors: Claudia Kleinschrodt, Bayreuth (DE); Stefan Hain, Speichersdorf (DE); Robert Maier, Neudrossenfeld (DE); Fabian Schötz, Illschwang (DE)

(73) Assignee: ZF Friedrichshafen AG, Friedrichshafen (DE)

(21) Appl. No.: 18/660,783

(22) Filed: May 10, 2024

(30) Foreign Application Priority Data
May 12, 2023 (DE) 10 2023 204 435.8

(51) Int. Cl. H02M 7/00; H05K 7/20

(52) U.S. Cl. CPC H02M 7/003; H05K 7/209

(57) ABSTRACT

A half-bridge arrangement includes an AC tap, DC taps, and a half-bridge including first and second topological switches formed from switch modules having semiconductor switches, each switch module having a flat top side with a cooling connection surface and an opposite underside, and side regions. A first current connection lug and signal pin project at first side regions of each switch module, and a second current connection lug projects at second side regions opposite the first side region. The switch modules are stacked so that current connection lugs of a first side region and a second side region lie one above another. Signal pin free ends point in the same direction, and the second current connection lug a switch module is provided along a partial region of the second side region and the signal pins of the other switch module are next to the second current connection lug.

### CROSS-REFERENCE TO RELATED APPLICATION

This application claims priority to German Application No. DE 10 2023 204 435.8, filed on May 12, 2023, the entirety of which is hereby fully incorporated by reference herein.

### FIELD

The present disclosure relates to the field of electromobility, in particular of electronics modules for an electric drive.

### BACKGROUND

The use of electronics modules, for example power electronics modules, in motor vehicles has increased significantly in recent decades. This can be attributed firstly to the need to improve the fuel saving and the vehicle performance and secondly to the advances in semiconductor technology. The main part of such an electronics module is a DC/AC inverter, which serves to energize electric machines such as electric motors or generators with a polyphase alternating current (AC). In this case, a direct current generated by a DC energy source, such as a battery, is converted into a polyphase alternating current. For this purpose, the inverters comprise a multiplicity of electronics components with which bridge circuits (for instance half-bridges) are realized, for example semiconductor power switches, which are also referred to as power semiconductors.

Power electronics arrangements or power electronics modules benefit both from a good cooling link and from a low-inductance commutation circuit. In this case, effective cooling links are connected in parallel and usually arranged on a board. This is disadvantageous with regard to the commutation cell since the DC current connections of the high-side HS and/or low-side LS switches are not equal in length and/or a high stray inductance arises, which is caused by the geometric arrangement. Furthermore, previously known cooling possibilities e.g. in the form of press-pack components require a specific construction, which reduces the component selection. Moreover, a clamping assembly is necessary, which is structurally complex.

In DE 10 2021 203 869 A1, provision is made of a cooling arrangement for power semiconductors which provides a small space requirement by virtue of half-bridges being stacked one on top of another. In that case, two topological switches of adjacent half-bridges each share a heat sink.

### SUMMARY

The present disclosure is based on an object of providing an even more compact half-bridge arrangement of an inverter.

This object is achieved by the features disclosed herein. Advantageous configurations are also the subject matter of the present disclosure.

What is proposed is a half-bridge arrangement of an inverter of an electric drive of a vehicle, wherein per AC phase provision is made of: at least one AC tap, and also DC taps, and at least one half-bridge formed from a first topological switch formed from one or more switch modules—surrounded by an electrically insulating material—having one or more first semiconductor switches, and a second topological switch formed from one or more switch modules—surrounded by an electrically insulating material—having one or more second semiconductor switches, wherein each switch module has a flat top side with a cooling connection surface arranged thereon and an underside opposite the top side, and also side regions connecting the top side and underside. A first current connection lug and also at least one signal pin arranged at a distance therefrom project at a first side region of each switch module, and a respective second current connection lug projects at a second side region opposite the first side region. The switch modules are arranged stacked one above another in such a way that respective current connection lugs of a first side region and of a second side region lie one above another and serve either as AC taps or as one of the DC taps. Free ends of the signal pins of the switch modules point in the same direction, and the second current connection lug of at least one of the switch modules is provided only along a partial region of the second side region and the signal pins of the other switch module are led next to the second current connection lug.

In one embodiment, the switch modules are arranged with their undersides toward one another and directly secured to one another.

In one embodiment, respective heat sinks are arranged on the cooling connection surfaces of the switch modules.

In one embodiment, the switch modules are arranged with their top sides toward one another, and a heat sink is provided, which is secured to both cooling connection surfaces of the switch modules.

In one embodiment, a printed circuit board is arranged in a region parallel to the top sides and undersides of the switch modules, and the switch modules are formed in such a way that the signal pins point in the direction of the printed circuit board and are contacted with the latter.

In one embodiment, the half-bridge arrangement furthermore comprises a signal rail, which is contacted with the printed circuit board and arranged in such a way that it contacts all the signal pins of a side region.

In one embodiment, provision is made of a plurality of half-bridges arranged stacked with their top sides and undersides parallel to one another.

Furthermore, an electronics module for controlling an electric drive of a vehicle is proposed, comprising an inverter having the half-bridge arrangement.

Furthermore, an electric drive of a vehicle comprising the electronics module formed for controlling the electric drive is proposed.

Furthermore, a vehicle comprising the electric drive is proposed.

Further features and advantages will become apparent from the following description of exemplary embodiments with reference to the figures of the drawing, which shows details according to the present disclosure, and from the claims. The individual features can each be implemented individually by themselves or as a plurality in any desired combination in a variant of the present disclosure.

Preferred embodiments of the present disclosure are explained in greater detail below with reference to the appended drawings.

### BRIEF DESCRIPTION OF THE DRAWINGS

FIG. 1 shows a plan view of a first switch module of the first topological switch of the half-bridge arrangement in accordance with one embodiment of the present disclosure.

FIG. 2 shows a plan view of a second switch module of the second topological switch of the half-bridge arrangement in accordance with one embodiment of the present disclosure.

FIG. 3 shows a plan view of a half-bridge arrangement formed from two switch modules stacked one above the other in accordance with one embodiment of the present disclosure.

FIG. 4 shows a side view of the half-bridge arrangement shown in FIG. 3.

FIG. 5 shows a side view of two half-bridge arrangements, which share a heat sink, in accordance with a further embodiment of the present disclosure.

FIG. 6 shows a side view of two half-bridge arrangements, which share a heat sink and the signal pins of which are led via a signal rail to a common printed circuit board, in accordance with a further embodiment of the present disclosure.

FIG. 7 shows a side view of two half-bridge arrangements, which share a heat sink, in accordance with a further embodiment of the present disclosure.

### DETAILED DESCRIPTION

In order to provide as compact a design of a half-bridge arrangement as possible, the following construction is proposed. In principle, a sandwich-like construction of the half-bridges is provided here, in the case of which the AC taps are arranged one above another, i.e. on the same side of all the half-bridges.

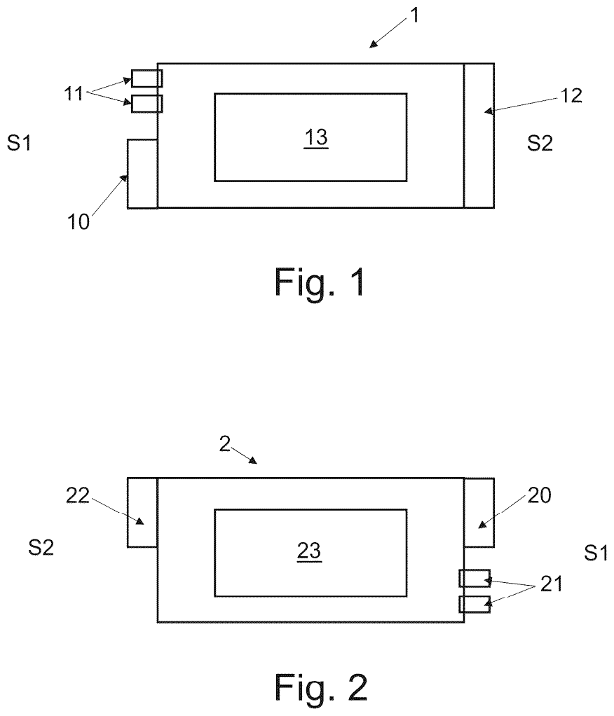

Each AC phase has an AC tap AC, input-side DC taps DC, i.e. in each case one DC positive tap and one DC negative tap, and also a half-bridge consisting of two topological switches connected in series. Each topological switch is formed from one or more switch modules 1 or 2 connected in parallel. The first switch module 1 is surrounded by an electrically insulating material (also referred to as mold) and has a first semiconductor switch, as shown in FIG. 1. The second switch module 2 is surrounded by an electrically insulating material, as shown in FIG. 2, and has a second semiconductor switch.

Each switch module 1, 2 has a flat top side with a cooling connection surface 13, 23 arranged thereon and an underside opposite the top side, and also side regions connecting the top side and underside, two side regions S1, S2 of which in each case are opposite one another. The two side regions S1 and S2 here are the mutually opposite (short) side regions at which the current connection lugs 10, 12, 20, 22 and the signal pins 11, 21 project from the respective switch module 1, 2. The current connection lugs 10, 20 serve as contacts for drain (MOSFET) or collector (IGBT) of the semiconductor switches, and the current connection lugs 12, 22 serve as contacts for source (MOSFET) or emitter (IGBT) of the semiconductor switches. The signal pins 11, 21 are arranged on one side region (on S1 in the embodiments), such that the current connection lug 10, 20 situated there shares the width of the side region S1 with the signal pins 11, 21. Current connection lug 10, 20 and signal pins 11, 21 are arranged along the width of the side region S1 and at a distance from one another. The number of signal pins 11, 21 can vary depending on the switch module 1, 2, provision always being made of at least one signal pin 11, 21, serving e.g. as a Kelvin source or as a gate signal pin.

The signal pins 11, 21 serve to transmit to the switch module 1, 2 signals from outside for controlling the switch state and can additionally offer the functionality of carrying signals from within the switch module 1, 2 toward the outside. In general, the signal pins 11, 21 are contacted with a printed circuit board 4 arranged in the region around the half-bridge, which printed circuit board then relays the signals via conductor tracks, e.g. to an ECU, i.e. a computing unit for processing the signals. The printed circuit board 4 is usually arranged at a distance parallel to a top side or underside of a switch module 1, 2, as indicated e.g. in FIGS. 4 to 7. In one embodiment, the printed circuit board 4 can also be led along a side region S1 or S2, such that signal pins 11 or 21 of all the half-bridges that project from this side region S1 or S2 can be equal in length and can be contacted directly with the printed circuit board 4.

Since, according to the present disclosure, switch modules 1, 2 are arranged stacked one above another, the contacting of the signal pins 11 of the lower switch module 1 with the printed circuit board 4 is difficult, since the current connection lugs 12, 22 previously extending over the entire side region S2, in particular those of the upper switch module 2, hinder bending of the signal pins 11 in the direction of the printed circuit board 4.

Since it is desirable for space reasons, too, to provide as compact a construction of the half-bridge arrangement as possible, it is proposed, as shown in FIGS. 1 to 3, to stack at least two switch modules 1, 2 one above another, wherein, in the embodiments shown, switch module 2 can be designated as upper switch module 2 and switch module 1 can be designated as lower switch module 1, since switch module 2 is arranged directly below the printed circuit board 4 and the signal pins 11 of the switch module 1 thus have to be led past switch module 2 to the printed circuit board 4. In order to achieve this, in the embodiment shown, the current connection lug 22 of at least the switch module 2 situated between printed circuit board 4 and lower switch module 1 is to be shortened, such that the current connection lug 22 is provided only along a partial region of the second side region S2. The signal pins 11 of the other switch module 1 situated underneath can thus be led next to the overlying current connection lug 22 of the module 2 situated between printed circuit board 4 and lower module 1. A shortened current connection lug 22 is shown e.g. in FIG. 2 for switch module 2. The length of the shortened current connection lug 22 is to be chosen such that signal pins 11 of the other switch module 1 that are to be led past the current connection lug 22 can be led in the free space at the necessary distance from the current connection lug 22, but also that the required current-carrying capacity of the current connection lug 22 is present.

In order to enable simplified production of the housings, i.e. in order to be able to produce all of the switch modules 1, 2 alike, the current connection lug 12, 22 of the side region S2 on which no signal pins 11, 21 are provided can always be implemented in a shortened fashion.

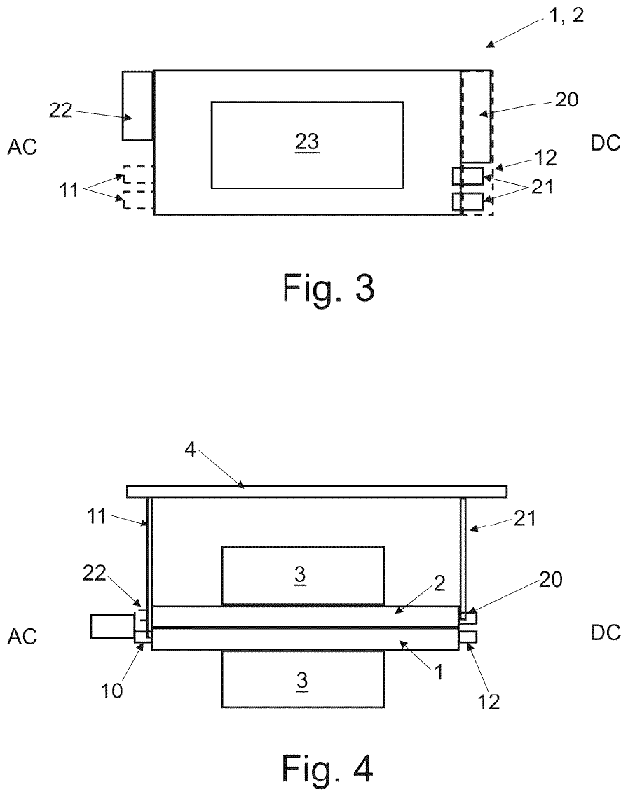

FIG. 3 shows a plan view of a stacked half-bridge in which the switch module 1 (with non-shortened current connection lug 12) is arranged below the switch module 2. FIG. 4 reveals a side view of the arrangement shown in FIG. 3, in which a printed circuit board 4 is additionally arranged above the switch module 2. The signal pins 11, 21 of both switch modules 1 and 2 are led in the direction of the printed circuit board 4 and contacted with the latter. Since the signal pins 11, 21 generally either project from the switch modules 1 and 2 without bending or are bent in the direction of the underside, it is necessary to bend the signal pins 11 or 21 of one of the switch modules 1 and 2 in order that the signal pins 11, 21 point in the same direction in a stacked arrangement. For this purpose, the signal pins 11 of the switch module 1 are longer than those of the switch module 2. Moreover, in this embodiment, the current connection lug 22 of the switch module 2 is shortened in order that the signal pins 11 of the switch module 1 arranged below that can be led to the printed circuit board 4 in a compact manner.

In FIGS. 3 and 4, the switch modules 1 and 2 are connected directly to one another and as far as possible without gaps at their undersides, i.e. at their electrically insulating material (mold or housing). The connection can be effected by adhesive bonding or by an external geometry. Their top sides each have a respective heat sink 3 arranged thereon, which serves for dissipating heat from the respective switch module 1 or 2. During production, either the undersides can firstly be connected to one another and then be thermally conductively connected to the heat sink 3, e.g. sintered onto the cooling connection surfaces 13, 23 or connected by a soldering process. Alternatively, firstly the heat sinks 3 can be conductively connected to the cooling connection surfaces 13, 23 and then the undersides can be connected to one another.

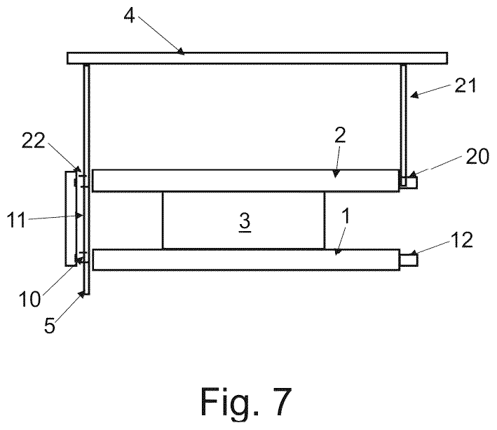

In an alternative embodiment shown in FIG. 7, the top sides of the two switch modules 1 and 2 face one another and a heat sink 3 is thermally connected to the cooling connection surfaces 13, 23. Consequently, two switch modules 1 and 2 share one heat sink.

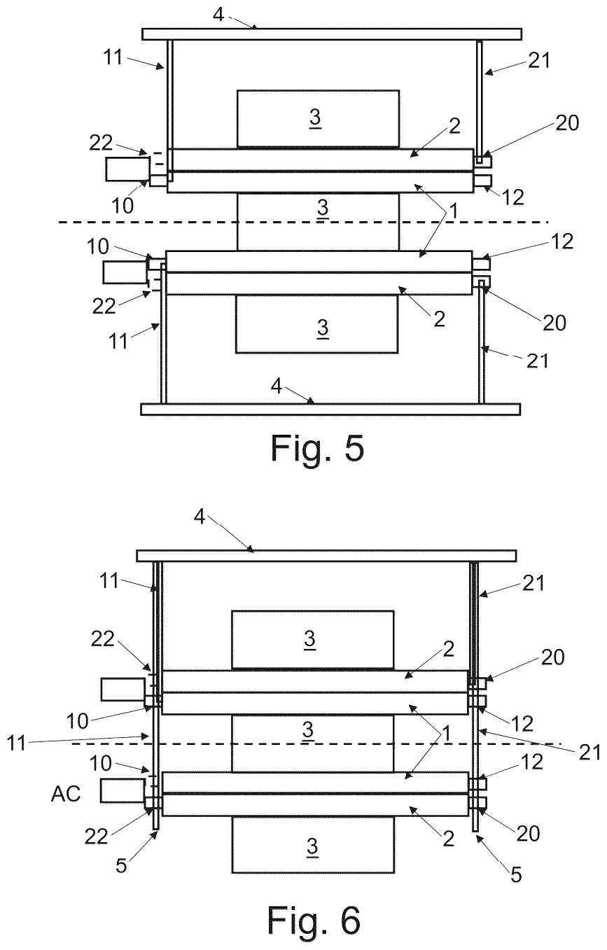

In an embodiment shown in FIG. 5, the half-bridge comprising the switch modules 1 and 2 is arranged in mirrored fashion at the lower heat sink 3 of the upper half-bridge (the middle heat sink 3 in FIG. 5), such that the switch module 1 facing the upper half-bridge shares the heat sink 3 with the switch module 1 of the upper half-bridge. However, it is also possible to provide mirroring upward or in both directions. Furthermore, the AC taps can be combined, thus resulting in a shared half-bridge.

In the embodiment shown in FIG. 5, two printed circuit boards 4 are provided, arranged respectively above the topmost heat sink 3 (of the upper half-bridge) and below the bottommost heat sink 3 (of the bottommost half-bridge). The signal pins of the upper half-bridge are contacted with the upper printed circuit board 4 and the signal pins of the lower half-bridge are contacted with the lower printed circuit board 4.

In an alternative embodiment, as shown in FIG. 6, it is also possible for just one printed circuit board 4 to be provided. In the embodiment shown, the printed circuit board 4 is arranged above the topmost heat sink 3 (of the upper half-bridge). However, it could also be arranged below the bottommost heat sink 3 (of the bottommost half-bridge). In this embodiment comprising just one printed circuit board 4, a signal rail 5 is provided on at least one side region S1 or S2, which signal rail extends over the entire height of the stacked half-bridges (two half-bridges are stacked here, but there may also be more) and is contacted with the signal pins 11 of one side region S1 or the signal pins 21 of the other side region S2 and also the printed circuit board 4. The signal rail 5 thus constitutes as it were a lengthening of the pins of the signal pins 11, 21. In an alternative embodiment, not shown, the arrangement shown in FIG. 6 can also be embodied such that, rather than identical switch modules (switch modules 1 in the embodiment shown in FIG. 6), switch module 1 and switch module 2 share a heat sink 3. If the AC taps are combined, this is a shared half-bridge.

In the figures, the switch module 1 is formed as a high-side switch and the switch module 2 is formed as a low-side switch, such that in FIGS. 3 and 4 the left-hand side of the switch modules 1 and 2 serves as an AC tap AC, and the current connection lug 12 arranged on the right-hand side serves as a DC positive tap and the current connection lug 20 serves as a DC negative tap. Other arrangements are also conceivable, however, in which for example one of the DC taps DC can be supplied by a signal rail 5, as indicated in FIGS. 5 and 6.

The semiconductor switches are connectable electrically and/or in terms of signaling, via the signal pins 11, 21, to a control unit such as an electronic control unit (ECU) of the vehicle. The control unit is therefore able to control the semiconductor switches for the purpose of operating the electric drive, in particular for the purpose of energizing the electric machine, of a vehicle equipped with a corresponding drive. The printed circuit board can be formed e.g. as a circuit board (e.g. PCB) or a flexible printed circuit board.

Depending on the power demand, more or fewer modules can be connected in parallel in this arrangement, without a disadvantageous effect on their electrical link.

The surface area-to-volume ratio and thus the installation space as well are optimized by the proposed half-bridge arrangement.

In addition, provision is made of an electronics module having an inverter having a proposed half-bridge arrangement. The electronics module serves for controlling an electric drive of a vehicle. Furthermore, an electric drive and a vehicle are provided.

In the context of this disclosure, an electronics module serves for operating an electric drive of a vehicle, in particular of an electric vehicle and/or of a hybrid vehicle. The electronics module comprises a DC/AC inverter having the described inverter construction or part thereof. In addition, the electronics module can comprise an AC/DC rectifier, a DC/DC converter, a transformer and/or some other electrical converter or a portion of such a converter or can be a portion thereof. In particular, the electronics module serves for energizing an electric drive or an electric machine, for example an electric motor and/or a generator. A DC/AC inverter preferably serves for generating a polyphase alternating current from a direct current generated by a DC voltage of an energy source, for example a battery.

### LIST OF REFERENCE SIGNS

1, 2 Switch module
DC DC tap
AC AC tap
10, 20 First current connection lug
11, 21 Signal pins
12, 22 Second current connection lug
13, 23 Cooling connection surfaces
3 Heat sink
4 Printed circuit board
5 Signal rail
S1 First side region
S2 Second side region

1. A half-bridge arrangement of an inverter of an electric drive of a vehicle, comprising, per AC phase:
at least one AC tap, and DC taps; and
at least one half-bridge comprising:
a first topological switch formed from one or more switch modules, surrounded by an electrically insulating material, and having one or more first semiconductor switches; and
a second topological switch formed from one or more switch modules, surrounded by an electrically insulating material, and having one or more second semiconductor switches,
wherein each of the one or more switch modules of the first topological switch and the second topological switch has a flat top side with a cooling connection surface arranged thereon, and an underside opposite the top side, and side regions connecting the top side and underside,
wherein a first current connection lug and at least one signal pin arranged at a distance from the first current connection lug project at a first side region of each switch module, and a respective second current connection lug projects at a second side region of each switch model opposite the first side region,
wherein the switch modules are arranged stacked one above another such that respective current connection lugs of the first side region and of the second side region lie one above another and serve either as AC taps or as one of the DC taps,
wherein free ends of the at least one signal pin of the switch modules point in a same direction, and
wherein the second current connection lug of at least one of the switch modules is provided only along a partial region of the second side region, and the at least one signal pin of another switch module are led next to the second current connection lug.

2. The half-bridge arrangement according to claim 1, wherein the one or more switch modules are arranged with their undersides toward one another and directly secured to one another.

3. The half-bridge arrangement according to claim 2, wherein respective heat sinks are arranged on the cooling connection surfaces of the one or more switch modules.

4. The half-bridge arrangement according to claim 1, wherein respective heat sinks are arranged on the cooling connection surfaces of the one or more switch modules.

5. The half-bridge arrangement according to claim 1, wherein the one or more switch modules are arranged with their top sides toward one another, and wherein a heat sink is provided, which is secured to the cooling connection surfaces of the one or more switch modules.

6. The half-bridge arrangement according to claim 1, wherein a printed circuit board is arranged in a region parallel to the top sides and undersides of the one or more switch modules, and wherein the one or more switch modules are formed such that the at least one signal pin point in a direction of the printed circuit board and are contacted with the printed circuit board.

7. The half-bridge arrangement according to claim 1, comprising:
a signal rail, which is contacted with the printed circuit board and arranged such that it contacts all of the one or more signal pins of a side region.

8. The half-bridge arrangement according to claim 1, comprising:
a plurality of half-bridges arranged stacked with their top sides and undersides parallel to one another.

9. An electronics module for controlling an electric drive of a vehicle, comprising:
an inverter comprising the half-bridge arrangement according to claim 1.

10. An electric drive of a vehicle, comprising:
the electronics module for controlling the electric drive according to claim 9.

11. A vehicle, comprising:
the electric drive according to claim 10.

12. The half-bridge arrangement according to claim 2, wherein a printed circuit board is arranged in a region parallel to the top sides and undersides of the one or more switch modules, and wherein the one or more switch modules are formed such that the at least one signal pin point in a direction of the printed circuit board and are contacted with the printed circuit board.

13. The half-bridge arrangement according to claim 2, comprising:
a signal rail, which is contacted with the printed circuit board and arranged such that it contacts all of the one or more signal pins of a side region.

14. The half-bridge arrangement according to claim 2, comprising:
a plurality of half-bridges arranged stacked with their top sides and undersides parallel to one another.

15. The half-bridge arrangement according to claim 4, wherein a printed circuit board is arranged in a region parallel to the top sides and undersides of the one or more switch modules, and wherein the one or more switch modules are formed such that the at least one signal pin point in a direction of the printed circuit board and are contacted with the printed circuit board.

16. The half-bridge arrangement according to claim 4, comprising:
a signal rail, which is contacted with the printed circuit board and arranged such that it contacts all of the one or more signal pins of a side region.

17. The half-bridge arrangement according to claim 4, comprising:
a plurality of half-bridges arranged stacked with their top sides and undersides parallel to one another.

18. The half-bridge arrangement according to claim 5, wherein a printed circuit board is arranged in a region parallel to the top sides and undersides of the one or more switch modules, and wherein the one or more switch modules are formed such that the at least one signal pin point in a direction of the printed circuit board and are contacted with the printed circuit board.

19. The half-bridge arrangement according to claim 5, comprising:
a signal rail, which is contacted with the printed circuit board and arranged such that it contacts all of the one or more signal pins of a side region.

20. The half-bridge arrangement according to claim 5, comprising:
a plurality of half-bridges arranged stacked with their top sides and undersides parallel to one another.
